(19) United States
(12) Patent Application Publication
(10) Pub. No.: US 2023/0180490 A1
(43) Pub. Date: Jun. 8, 2023

(54) PRINTABLE HOLE CONDUCTOR FREE MESOPOROUS INDIUM TIN OXIDE BASED PEROVSKITE SOLAR CELLS

(71) Applicant: Yissum Research Development Company of the Hebrew University of Jerusalem Ltd., Jerusalem (IL)

(72) Inventors: Lioz ETGAR, Jerusalem (IL); Avraham SCHNEIDER, Mevaseret Zion (IL); Ariel EFRATI, Jerusalem (IL)

(73) Assignee: Yissum Research Development Company of the Hebrew University of Jerusalem Ltd., Jerusalem (IL)

(21) Appl. No.: 17/995,280

(22) PCT Filed: Mar. 31, 2021
(86) PCT No.: PCT/IL2021/050363

§ 371 Date: Sep. 30, 2022

Related U.S. Application Data
(60) Provisional application No. 63/004,618, filed on Apr. 3, 2020.

(51) Int. Cl. H10K 30/50; H10K 30/20; H10K 71/60

(52) U.S. Cl. CPC H10K 30/50; H10K 30/20; H10K 71/611

(57) ABSTRACT

Provided is a perovskite-based photovoltaic device including a layered scaffold material and at least one perovskite material interpenetrating the layered scaffold, wherein the at least one perovskite layer is removable and regenerable.

### TECHNOLOGICAL FIELD

The invention generally concerns printable perovskite solar cells and methods for their construction.

### BACKGROUND

Elevating world temperatures along climatic model predictions hasten the need of global economy to move towards green renewable energy production. On the photovoltaic branch, organic, inorganic and photosynthetic light harvesters were investigated extensively. In recent years, organic-inorganic perovskite solar cells (PSCs) have been breaking efficiency records towards the Shockley-Queisser limit. This has made PSCs, especially fully printable panels, prominent candidates for a large scale commercialization. At the same time, a tremendous effort to stabilize the perovskite intrinsic properties has been made by the research of different compositions and fabrication methods. These efforts include the introduction of hole conductor free configurations, two-dimensional perovskite compositions and recently the usage of methylammonium free compounds.

Typically, photo-induced charge separation in the perovskite semiconductor is coupled with an electron transporting layer (ETL) of mesoporous TiO₂ (mpTiO₂) on one side, and a hole transporting material (HTM) on the other. Traditionally, a metal cathode is evaporated onto the cell—sealing the basic functional structure of the solar device. A more scalable approach utilizes a porous carbon layer as the cathode of the cell, allowing the perovskite precursor solution to percolate through the pores and crystalize inside the structure. This method uses the conductive characteristics of the carbonated material and its ability to inject electrons efficiently to the perovskite, allowing anisotropic average diffusion of the charges without HTM.

GENERAL DESCRIPTION

The technology disclosed herein provides a new approach of an all-nanoparticle, inorganic, fully printed (screen-printed) mesoporous scaffold for perovskite solar cells. A layered structure of sintered nanoparticles (NPs) was designed as a general scaffold for various perovskite compositions and deposition methods. The key component of this approach is a conductive mesoporous ITO (mpITO) contact which is insulated by a ZrO₂ layer from the electron transporting layer (ETL). This forms a complete scaffold configuration having the structure FTO/TiO₂/mpZrO₂/mpITO. A Perovskite solution can then be applied directly on the mpITO contact. Subsequently, a three dimensional network of perovskite crystallizes in cavities present between the NPs. As the ITO contact provides direct electron injection to the perovskite under illumination, no further additional processing steps are required and the cell is functional.

While deposition of a specific perovskite is demonstrated, e.g., (MA_{0.15}FA_{0.85})PbI₃, a device according to the invention may be formed with any perovskite material known in the art. Scalable solar cells formed according to the invention exhibited high short circuit currents, impressive stability and the unique possibility for recycling by removing and reapplying damaged or degraded perovskite.

Thus, in most general terms, the invention concerns a perovskite-based photovoltaic (solar cell) device comprising a layered scaffold structure and at least one perovskite material interpenetrating said layered scaffold structure.

The invention also provides a perovskite-based photovoltaic (solar cell) device comprising a layered scaffold structure and at least one removable perovskite material interpenetrating said layered scaffold structure.

As described hereinbelow, the at least one perovskite layer is peelable or generally removable from the layered scaffold on which it is formed. As used herein, the term or “removal”, “peelable” or any equivalent terminology or lingual variation suggests the ability of the perovskite layer to be peeled off or removed or detached from the surface of the layered scaffold on which it was formed. The term also encompasses the ability to regenerate the perovskite layer by forming a new layer on the surface of the scaffold in place of the perovskite layer which was removed. Thus, when forming a perovskite layer on the layered scaffold, the layer is configured to be “peelable and regenerable”, meaning capable of being removed and reapplied to reconstitute a perovskite-based device as disclosed herein.

The device of the invention is an all-particle inorganic or organic-inorganic device constructed of a layered scaffold material and a layer of at least one perovskite material that interpenetrates between the particulate matters constituting the scaffold. The “layered scaffold structure” is constructed of alternating conductive/insulating material layers, each being of conductive or insulating particulate materials, respectively, thereby forming a layered structure through which the perovskite material can penetrate. In some embodiments, the scaffold structure is formed on a surface of a substrate or a functional substrate, such as a photoanode, e.g., conductive fluorine doped tin oxide (FTO) coated glass, forming a device according to the invention.

The scaffold structure comprises a plurality of layers, structured as a stack of layers or as a multilayered structure. The layers comprise or consist:
a transparent layer of a conductive metal oxide material (such as TiO₂, or ZnO) that intimately covers a substrate, e.g., a glass or a polymer substrate that acts as a photoanode, this transparent layer may be mesoporous, compact or crystalline;
a layer of an insulating metal oxide material (such as ZrO₂, or Al₂O₃) that covers the conductive metal oxide, e.g., mesoporous TiO₂, layer, and which may be in a mesoporous form; and
a top-most layer of a conductive indium tin oxide (ITO), which may be mesoporous, or a layer of fluorine doped tin oxide (FTO) nanoparticles (NPs) that covers the layer of the insulating metal oxide material. This top-most ITO or FTO layer is configured to accept a layer of at least one perovskite material that interpenetrates the scaffold layers.

In some embodiments, a device of the invention is free of a blocking layer, namely free of a compact or dense (not mesoporous) TiO₂ layer. This layer may be of any thickness; however, in some embodiments, devices of the invention are free of a dense TiO₂ layer or film having a thickness of between 50 and 100 nm.

In some embodiments, the scaffold structure has the following form:

Layer 1—formed on e.g., a photoanode (glass, polymer or another material or a substrate): a conductive metal oxide layer, comprising or consisting at least one mesoporous conductive metal oxide such as TiO₂ and/or ZnO;

Layer 2—formed on Layer 1: an insulating metal oxide layer, comprising or consisting at least one mesoporous insulating metal oxide such as e.g., ZrO₂ and/or Al₂O₃;

Layer 3—formed on Layer 2: an ITO or FTO NPs layer, comprising or consisting at least one mesoporous ITO or FTO NPs.

A perovskite layer (being Layer 4 in this set-up) covers or overlays at least a region of Layer 3 and interpenetrates the scaffold structure (Layers 3, 2 and 1).

Thus, in most general terms, the scaffold structure of the invention has the structure: [a conductive metal oxide layer]/[an insulating metal oxide layer]/[an ITO or FTO NPs layer]. When on a substrate, e.g., a photoanode material, the scaffold structure is: [photoanode]/[a conductive metal oxide layer]/[an insulating metal oxide layer]/[an ITO or FTO NPs layer].

With a perovskite layer on the top-most layer, the perovskite-scaffold structure is [a conductive metal oxide layer]/[an insulating metal oxide layer]/[an ITO or FTO NPs layer]/[perovskite layer].

A complete device thus comprises [photoanode]/[a conductive metal oxide layer]/[an insulating metal oxide layer]/[an ITO or FTO NPs layer]/[perovskite layer], as depicted in the figures.

Each of the brackets “[ . . . ]” indicates a distinct layer.

The conductive metal oxide may be in a form of a mesoporous material or in a form other than a mesoporous form, such as compact or crystalline forms. In some embodiments, each of the conductive and insulating materials is provided in a mesoporous form.

Thus, a scaffold structure of the invention may be of the structure:

Layer 1—formed on e.g., a photoanode: a conductive metal oxide, which may be provided as a mesoporous layer, as an amorphous mesoporous form, in a crystalline mesoporous form or in a compact form;

Layer 2—formed on Layer 1: a mesoporous insulating metal oxide;

Layer 3—formed on Layer 2: a mesoporous ITO or FTO NPs.

As used herein, the term “mesoporous” refers to a characteristic of a particular material or a material layer containing pores with varying diameters (depending inter alia on the material and layer characteristics). Typically, the pores are voids formed in the layer or between particles in the layer, having diameters between 2 and 50 nm, allowing interpenetration of the perovskite material via the pores and through the layers. The mesoporous form may be ordered or disordered yielding crystalline mesoporous forms and amorphous mesoporous forms, respectively.

Contrary to compact materials, the surface area of mesoporous materials is usually high with a narrow pore size distribution. In some configurations, the materials and layers disclosed herein may be provided in compact form, namely exhibiting reduced porosity and increased compactness.

As stated herein, devices of the invention are all-particle inorganic devices, namely each of the scaffold and perovskite layers comprise or consist a plurality of particulate inorganic materials (nanoparticles and/or microparticles). The scaffold structure and the perovskite layer in devices of the invention are free of non-particulate materials.

In some embodiments, the TiO₂ is provided in the form of nanoparticles having a size ranging from between 10 and 30 nm. In some embodiments, the TiO₂ is provided in the form of nanoparticles having a size of 20 nm.

In some embodiments, the ZrO₂ is provided in the form of nanoparticles having a size ranging from between 10 and 50 nm. In some embodiments, the ZrO₂ is provided in the form of nanoparticles having a size ranging from between 20 and 40 nm or about 30 nm.

In some embodiments, the ITO is provided in the form of nanoparticles having a size ranging from between 30 and 70 nm. In some embodiments, the ITO is provided in the form of nanoparticles having a size ranging from between 40 and 60 nm or 50 nm.

In some embodiments, the ITO is doped with a conductive material, such as a conductive metal in order to improve conductivity while maintaining transparency. The dopant may be a metal such as Cu, Mo, Ag, and others.

The thickness of each of the scaffold and perovskite layers may be in the nanoscale or the microscale and may be tuned. In some embodiments, the thickness of each layer is in the microscale, ranging between 1 and 5 micron. In some embodiments, the ITO layer thickness is between 2 and 5 micron while the thickness of the metal oxide layers (conductive or insulating layers) is between 1 and 3 microns.

The scaffold structures in devices of the invention are free of organic materials or organic matrix materials. In other words, the layers of the scaffold material consist of the conducting or insulating materials, in any of the particular forms, and absent any organic matrix materials that may be used as encapsulating or comprising the conducting or insulating materials. It should be noted that while the scaffold structure is free of organic materials, the perovskite layer may be an inorganic layer or an inorganic-organic hybrid layer.

In some embodiments, the conductive metal oxide is provided as an amorphous mesoporous layer, or as a crystalline mesoporous layer.

In some embodiments, the conductive metal oxide is provided as a compact layer.

In some embodiments, the device is of the form FTO/compact TiO₂/mpZrO₂/mpITO/Perovskite, wherein “mp” stands for mesoporous.

In some embodiments, the device is of the form FTO/crystalline mpTiO₂/mpZrO₂/mpITO/Perovskite, wherein “mp” stands for mesoporous.

In some embodiments, the device is of the form FTO/amorphous mpTiO₂/mpZrO₂/mpITO/Perovskite, wherein “mp” stands for mesoporous.

In some embodiments, the device is of the form FTO/compact TiO₂/mpZrO₂/FTO np/Perovskite, wherein “mp” stands for mesoporous and “np” stands for nanoparticles.

In some embodiments, the device is of the form FTO/crystalline mpTiO₂/mpZrO₂/FTO np/Perovskite, wherein “mp” stands for mesoporous and “np” stands for nanoparticles.

In some embodiments, the device is of the form FTO/amorphous mpTiO₂/mpZrO₂/FTO np/Perovskite, wherein “mp” stands for mesoporous and “np” stands for nanoparticles.

Devices of the invention are further unique in the ability to be fully manufactured by printing, e.g., by any printing means known in the art capable of printing high viscosity or paste materials, e.g., 3D printing, inkjet printing, screen printing and silk printing. Thus, the invention also provides a printed device comprising a scaffold structure, as defined herein, and a perovskite layer, wherein the scaffold structure and the perovskite layer are free of non-particulate materials and the scaffold structure further being free of organic materials.

Devices of the invention may be used and re-used by rejuvenating or restoring the perovskite layer. Where a device of the invention deteriorates upon continued use, the perovskite layer may be washed off or otherwise removed without negatively affecting the scaffold structure on top of which it is formed. Thus, where needed, the perovskite layer may be removed and a new layer may be formed to thereby restore full functionality of the device.

Thus, devices of the invention are reusable devices.

The perovskite material used in accordance with the invention comprises or consists one or more perovskite species, encompassing any perovskite structure known in the art. The perovskite material is typically characterized by the structural motif AMX₃, having a three-dimensional network of corner-sharing MX₆ octahedra, wherein M is a metal cation that may adopt an octahedral coordination of the X anions, and wherein A is a cation typically situated in the 12-fold coordinated holes between the MX₆ octahedra.

In some embodiments, A and M are metal cations, i.e., the perovskite material is a metal oxide perovskite material. In other embodiments, A is an organic cation and M is a metal cation, i.e., the perovskite material is an organic-inorganic perovskite material.

In some embodiments, the perovskite material is of the formula:

AMX₃ or

AMX₄ or

A₂MX₄ or

A₃MX₅ or

A₂AMX₅ or

AMX₃₋ₙX′ₘ,

wherein, in each of the above formulae, independently:

each A and A′ are independently selected from organic cations, metal cations and any combination of such cations;

M is a metal cation or any combination of metal cations;

each X and X′ are independently selected from anions and any combination of anions; and

n is between 0 to 3.

The metal cations may be selected from metal element of Groups IIIB, IVB, VB, VIB, VIIB, VIIIB, IB, IIB, IIIA, IVA and VA of block d of the Periodic Table of the Elements.

In some embodiments, the metal cation is Li or Mg or Na or K or Rb or Cs or Be or Ca or Sr or Ba, Sc or Ti or V or Cr or Fe or Ni or Cu or Zn or Y or La or Zr or Nb or Tc or Ru or Mo or Rh or W or Au or Pt or Pd or Ag or Co or Cd or Hf or Ta or Re or Os or Ir or Hg or B or Al or Ga or In or Tl or C or Si or Ge or Sn or Pb or P or As or Sb or Bi or O or S or Se or Te or Po or any combination thereof.

In some embodiments, the metal cation is a transition metal selected from Groups IIIB, IVB, VB, VIB, VIIB, VIIIB, IB and IIB of block d the Periodic Table. In some embodiments, the transition metal is a metal selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg or any combination thereof.

In some embodiments, the metal cation is a post-transition metal selected from Group IIIA, IVA and VA. In some embodiments, the metal cation is Al or Ga or In or Tl or Sn or Pb or Bi or any combination thereof.

In some embodiments, the metal cation is a semi-metal selected from Group IIIA, IVA, VA and VIA. In some embodiments, the metal cation is B or Si or Ge or As or Sb or Po or any combination thereof.

In some embodiments, the metal cation is an alkali metal selected from Group IA. In some embodiments, the metal cation is an alkali metal Li or Mg or Na or K or Rb or Cs.

In some embodiments, the metal cation is an alkaline earth metal selected from Group IIA. In some embodiments, the metal cation is Be or Ca or Sr or Ba.

In some embodiments, the metal cation is a lanthanide element such as Ce or Pr or Gd or Eu or Tb or Dy or Er or Tm or Nd or Yb or any combination thereof.

In some embodiments, the metal cation is an actinides element such as Ac or Th or Pa or U or Np or Pu or Am or Cm or Bk or Cf or Es or Fm or Md or No or Lr or any combination thereof.

In some embodiments, the metal cation is a divalent metal cation. Non-limiting examples of divalent metals include Cu⁺², Ni⁺², Co⁺², Fe^{30 2}, Mn⁺², Cr⁺², Pd⁺², Cd⁺², Ge⁺², Sn⁺², Pb⁺², Eu⁺² and Yb⁺².

In some embodiments, the metal cation is a trivalent metal cation. Non-limiting examples of trivalent metals include Bi⁺³ and Sb⁺³.

In some embodiments, the metal cation is Pb⁺².

The organic cations comprise at least one organic moiety (containing one or more carbon chain or hydrocarbon chain or one or more organic group). The organic moiety may be selected from substituted or unsubstituted alkyl, substituted or unsubstituted alkenyl, substituted or unsubstituted alkynyl, substituted or unsubstituted cycloalkyl, substituted or unsubstituted cycloalkenyl, substituted or unsubstituted cycloalkynyl, substituted or unsubstituted aryl, substituted or unsubstituted heteroaryl, substituted or unsubstituted heterocyclyl, substituted or unsubstituted —NR₁R₂, substituted or unsubstituted —OR₃, substituted or unsubstituted —SR₄, substituted or unsubstituted —S(O)R₅, substituted or unsubstituted alkylene-COOH, and substituted or unsubstituted ester.

The variable group denoted by “R”, in any one of the generic descriptions e.g., —NR₁R₂, —OR₃, —SR₄, —S(O)R₅, refers to one or more group selected from hydrogen, alkyl, alkenyl, alkynyl, cycloalkyl, cycloalkenyl, cycloalkynyl, aryl, heteroaryl, heterocyclyl, halogen, alkylene-COOH, ester, —OH, —SH, and —NH, as defined herein or any combination thereof. In some embodiments, the number of R groups may be 0 or 1 or 2 or 3 or 4 or 5 or 6 or 7 or 8 or 9 or 20. As used herein, the group R refers generically to any specific R used herein, unless a specific definition is provided; in other words, the aforementioned definition refers to any of the R groups, e.g., R′, R″, R′″, R″″, R₂, R₃, R₄, R₅, R₆, R₇, R₈, etc, unless otherwise specifically noted.

In some embodiments, the at least one anion is an organic anion or an inorganic anion as known in the art. In some embodiments, the anion is a halide ion (F, Br, Cl, or I).

In some embodiments, the perovskite material is a single species of a perovskite material. In other embodiments, the perovskite material is a combination of two or more (several) different species of different perovskite materials. In some embodiments, the number of different species of different perovskite materials may be 2 or 3 or 4 or 5 or 6 or 7 or 8 or 9 or 10 different perovskite species.

In some embodiments, the perovskite material is provided as a multilayered structure of layered perovskite materials, wherein each layer is of the same or different perovskite material.

In some embodiments, where the perovskite materials in the different layers are different, the difference may be in the species of a perovskite material, a mixture of several different species of perovskite materials, the ratio between the different perovskite materials, etc. In some embodiments, each layer in a perovskite multilayer is made of a different combination or the same combination but with different ratios of perovskite materials.

In some embodiments, where the perovskite material is in a form of a multilayered perovskite material, each of the perovskite layers in the multilayer may be of the same perovskite material or of different perovskite materials. In some embodiments, the multilayer perovskite comprises 2 or 3 or 4 or 5 or 6 or 7 or 8 or 9 or 10 perovskite layers.

In some embodiments, the perovskite material comprises 2 or 3 or 4 or 5 or 6 or 7 or 8 or 9 or 10 different perovskite materials, each being selected and defined as above.

In some embodiments, the perovskite material comprises two perovskite materials at a ratio of 1:1 or 1:2 or 1:3 or 1:4 or 1:5 or 1:6 or 1:7 or 1:8 or 1:9 or 1:10 or 1:100 or 1:200 or 1:300 or 1:400 or 1:500.

In some embodiments, the perovskite material is of the structure APbI₃, wherein A is an amine (or corresponding ammonium) or at least one amine (or corresponding ammonium) compound such that where the number of amines is greater than 1, the ratio amine(s):Pb is 1.

In some embodiments, the at least one amine (or corresponding ammonium) is selected from aromatic and aliphatic amines. In some embodiments, the amine is formamidine (FA) and/or methylamine (MA). In some embodiments, the amine is a combination of formamidine and methylamine.

In some embodiments, the perovskite is selected from FAₓMAₓ₋₁Y, wherein Y is the perovskite species and wherein 0<=x<=1, such systems may be FA_{0.85}MA_{0.15}PbI₃, FA_{0.85}MA_{0.15}PbI₂Br, FA_{0.85}MA_{0.15}PbIBr₂, and others. Additional perovskites may be Cs_{0.15}FA_{0.75}MA_{0.10}PbI₂Br, Cs_{0.15}FA_{0.85}PbI₂Br and others.

In some embodiments, the perovskite layer comprises or consists an inorganic perovskite material. In some embodiments, the perovskite layer comprises or consists an inorganic-organic perovskite material.

The invention also provides a process for manufacturing a perovskite-based device comprising a layered scaffold material and at least one perovskite material interpenetrating said layered scaffold, the process comprising forming on a layered scaffold material, being free of organic materials, a layer of at least one perovskite material under conditions permitting interpenetration of the at least one perovskite material through the scaffold material.

In some embodiments, the process comprises forming the layered scaffold material by stacking alternate layers of insulating and conducting particulate materials, said layered scaffold material being free of organic materials, and overlaying said layered scaffold material with a layer of at least one perovskite material under conditions permitting interpenetration of the at least one perovskite material through the scaffold material

The invention further provides a process for the manufacture of device according to the invention, the process comprising:
forming a layer of at least one conductive metal oxide material on a substrate, the at least one conductive metal oxide may be in a form selected to provide a mesoporous layer, an amorphous mesoporous layer or a crystalline mesoporous layer or a compact layer; or the conditions of forming the layer are selected to provide a mesoporous layer, an amorphous mesoporous layer or a crystalline mesoporous layer or a compact layer;
forming a layer of at least one insulating metal oxide material on said layer of at least one conductive metal oxide material;
forming a layer of ITO or FTO on said layer of at least one insulating metal oxide material; and
forming a perovskite layer on said ITO or FTO layer under conditions permitting penetration of said perovskite material through all mesoporous layers.

In some embodiments, one or more or all of the process steps is conducted by printing.

In some embodiments, the process comprises:
forming, optionally by printing, a layer, as defined herein, of at least one conductive metal oxide material on a substrate;
forming, optionally by printing, a layer of at least one insulating metal oxide material on said layer of at least one conductive metal oxide material;
forming, optionally by printing, a layer of ITO or FTO on said layer of at least one insulating metal oxide material; and
forming, optionally by printing, a perovskite layer on said ITO or FTO layer under conditions permitting penetration of said perovskite material through all layers.

In some embodiments, all or at least one of the layers or layer materials is mesoporous. In some embodiments, the layer of the at least one insulating metal oxide material is mesoporous. In some embodiments, the at least one conductive metal oxide material is mesoporous.

In some embodiments, each of said at least one conductive metal oxide material, at least one insulating metal oxide material and ITO or FTO are provided as a paste.

In some embodiments, the at least one conductive metal oxide material is selected as above.

In some embodiments, the at least one insulating metal oxide material is selected as above.

In some embodiments, the process is for fabricating a device of the form FTO/TiO₂/mpZrO₂/mpITO/Perovskite, wherein the TiO₂ may be provided as a mesoporous layer, an amorphous mesoporous layer or a crystalline mesoporous layer or a compact layer.

In some embodiments, the conductive metal oxide, e.g., TiO₂, is provided in the form of a paste as nanoparticles having a size ranging from between 10 and 30 nm. In some embodiments, the size is 20 nm.

In some embodiments, the insulating metal oxide, e.g., ZrO₂, is provided in the form of a paste as nanoparticles having a size ranging from between 10 and 50 nm. In some embodiments, the size ranges from between 20 and 40 nm or about 30 nm.

In some embodiments, the ITO is provided in the paste in the form of nanoparticles having a size ranging from between 30 and 70 nm. In some embodiments, the ITO is provided in the form of nanoparticles having a size ranging from between 40 and 60 nm or 50 nm.

As stated herein, the perovskite layer is formed under conditions permitting penetration of said perovskite material through the scaffold, e.g., mesoporous, layers. These conditions include first casting or applying or adding a metal halide, e.g., PbI₂, onto the ITO layer, and thermally treating the cast/applied metal halide. Thereafter, the annealed cast/applied metal halide is treated with an organic ligand, e.g., an amine, and thermally annealed to provide a perovskite surface.

The invention further provides a system utilizing or implementing a device according to the invention. In some embodiments, the system may be a photovoltaic cell, a LED or a lasing device.

In some embodiments, the system comprises a scaffold structure as disclosed herein.

The invention also provides use of a scaffold structure according to the invention in the production of a device, such as a photovoltaic cell, a LED or a lasing device.

As indicated herein, the scaffold structure is constructed of alternating conductive/insulating material layers, each being of conductive or insulating particulate materials, respectively. In some embodiments, the scaffold structure is formed on a surface of a substrate or a functional substrate, such as a photoanode, e.g., conductive fluorine doped tin oxide (FTO) coated glass, forming a device according to the invention.

In some embodiments, the scaffold structure comprises a plurality of layers, structured as a stack of layers or as a multilayered structure. The layers comprise or consist:
a transparent layer of a conductive metal oxide material (such as TiO₂, or ZnO) that intimately covers a substrate, e.g., a glass or a polymer substrate that acts as a photoanode, this transparent layer may be mesoporous, compact or crystalline;
a layer of an insulating metal oxide material (such as ZrO₂, or Al₂O₃) that covers the conductive metal oxide, e.g., mesoporous TiO₂, layer, and which may be in a mesoporous form; and
a top-most layer of a conductive indium tin oxide (no), which may be mesoporous, or a layer of fluorine doped tin oxide (FTO) nanoparticles (NPs) that covers the layer of the insulating metal oxide material. This top-most ITO or FTO layer is configured to accept a layer of at least one perovskite material that interpenetrates the scaffold layers.

In some embodiments, the device comprises a perovskite layer.

In a use of a scaffold structure in a method of producing a device, the scaffold structure comprising or consisting:
a transparent layer of a conductive metal oxide material, as detailed herein;
a layer of an insulating metal oxide material, as detailed herein; and
a top-most layer of a conductive indium tin oxide (ITO), or a layer of fluorine doped tin oxide (FTO) nanoparticles (NPs), as detailed herein.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A-D depict a device architecture and physical, optical and electronic characterizations. (A) Illustration of FTO/mpTiO₂/mpZrO₂/mpITO cell design, according to some embodiments of the invention. The triple layered nanoparticle matrix is interweaved with a complimentary perovskite network which has crystalized within its cavities. Upon illumination, charge separation in the perovskite generates anodal and cathodal photocurrents in the FTO and ITO layers, respectively. (B) Illustration (left) and scanning electron micrograph (right) of a cell cross-section, presenting the arrangement of mpITO, mpZrO₂, mpTiO₂ and FTO functional layers atop a glass substrate as well as the penetration of perovskite through the porous layers. (C) Absorbance spectra of (1) FTO/mpTiO₂/mpZrO₂, (2) full scaffold including mpITO without perovskite and (3) a complete cell with FA_{0.85}MA_{0.15}PbI₃ perovskite. (D) Energy diagram showing the energy levels of all cell components.

FIGS. 2A-C present elemental mapping of a porous ITO perovskite solar cell cross-section using energy dispersive X-ray spectroscopy (EDS). (A) Spatial distribution, in terms of counts per second, of cell scaffold elements: (1) Indium (Lα1, blue), (2) Zirconium (Lα1, maroon), (3) Titanium (Kα1, green) and (4) Tin (Lα1, yellow) along the EDS line scan of a cell cross-section. (B) EDS line scan path along the layers, as labeled. (C) Spatial distribution, in terms of counts per second, of perovskite elements: (I) Lead (Mα1, black) and (II) Iodine (Lα1, red) along the EDS line scan of a cell cross section

FIGS. 3A-F provide photovoltaic characterization of ITO-PSCs with FA_{0.85}MA_{0.15}PbI₃ perovskite. (A) Current density vs. voltage (J-V) curve of best performing device under 100 mW/cm² (AM1.5G) illumination. (B) Typical incident photon to external quantum efficiency (EQE) measurement of the cells. (C—F) Measured value histogramme of (C) short circuit current density (Jsc), (D) open circuit voltage (Voc), (E) fill factor (FF) and (F) power conversion efficiency (PCE), for 40 ITO-PSCs along with a normal distribution curve centered around the average value.

FIGS. 4A-F demonstrate mesoporous ITO cell stability and restoration. (A-D) Trends in normalized values of (A) J_{sc}, (B) V_{oc}, (C) FF and (D) PCE for unencapsulated FA_{0.85}MA_{0.15}PbI₃ cells stored under ambient atmosphere over a period of 42 days. (E) Photographic account of two cell restoration cycles. DMF was used to wash away old perovskite, and new perovskite was deposited. (F) Changes in normalized values of J_{sc}, V_{oc}, FF and PCE over two restoration cycles. The error bars in all figures represent the standard deviation from the normalized value averaged over all measured cells.

FIGS. 5A-B show charge extraction and IMVS measurements. (A) Values of extracted charge as a function of delay time after illumination for (1) a ITO-PSC with FA_{0.85}MA_{0.15}PM₃ perovskite and (2) a typical porous carbon PSC with the same perovskite composition (B) The first observed lifetime as a function of light intensity (semi-logarithmic scale), calculated from IMVS measurements of (1) a FA_{0.85}MA_{0.15}PbI₃ ITO-PSC and (2) a carbon PSC with the same perovskite. Exponential decay fittings appear as dashed lines.

FIGS. 6A-D shows 4 current voltage curves of different ITO perovskite solar cells (Cells 577, 574, 550 and 554, respectively).

### DETAILED DESCRIPTION OF EMBODIMENTS

Methods

Materials and solvents. Hellmanex III, Titanium disopopoxide bis(acetylacetonate) (75% wt. in isopropanol), ethyl cellulose (46070 and 46080), terpineol, intium tin oxide (nanopowder <50 nm particle size), lead iodide (99%), N,N-dimethylformamide (anhydrous 99.8%), and isopropyl alcohol (anhydrous 99.5%) were purchased from Sigma-Aldrich. Formamidinium iodide (FAI), methylammonium iodide (MAI) and TiO₂ paste (90T) were purchased from GreatCell Solar Company. Zr-Nanoxide ZT/SP (46411) was purchased from Solaronix. Titanium (IV) chloride (TiCl₄) was purchased from Wako. Ethanol absolute (99.5%) and Dimethyl sulfoxide (DMSO, 99.7% Extra dry) were purchased from Acros Organics. A hyperthermic conductive carbon paste was purchased from FEIMING Chemical Ltd. All perovskite precursors and anhydrous solvents were kept in a nitrogen filled glove box and used as received.

Fabrication of ITO screen printing paste (Method I). For 1 g of ITO nano particles: in an 18 mL vial containing 8.9 mL ethanol absolute, 166 μL acetic acid, 830 μL triple distilled water, 1 gr of ITO powder was added in doses, the vial was shaken gently and tip sonicate between each dose. Then, the vial was stirred for 45 minutes before 0.9 g of terpineol was added and stirred for 10 minutes. 1.7 g of PVP solution was added and stirred for 1 hour. The medium was evaporated for ˜20 minutes in a rotor evaporator, starting at 30° C. and increased to 60° C.

The PVP solution was prepared by mixing 1 g of PVP 10K, 1 g of PVP 50K and 9 g of absolute ethanol until the PVP was completely dissolved.

Preparation of ITO nanoparticle paste (Method II). A solution of ethyl cellulose solution (10% wt.) was prepared by dissolving equal weights of two ethyl celluloses of different viscosities (Sigma 46070 and 46080) in ethanol and was magnetically stirred overnight. The ITO paste was prepared using a modified previously reported procedure. Briefly: 1.2 gr of ITO nanopowder were processed repeatedly using a mortar and pestle. First, five 1 min cycles of grinding were coupled with the adding of 200 μl triple distilled water (TDW) every cycle, then, fifteen 1 min grinding cycles ensued with the addition of 200 μl ethanol every cycle, followed by another six cycles with 500 μl fractions of ethanol. Once the grinding sequence was complete, the formed cement was diluted in 20 ml of ethanol and 1.95 gr of terpineol were added. The mixture was then dispersed using a magnetic stirrer and a sonic horn (50 half second pulses). Next, 2.88 gr of the cellulose solution were added and mixed similarly using a magnetic stirrer and sonic horn. The mixture was finally stirred on a hot plate at 50° C. for 24 h until the ethanol was evaporated completely.

mpITO scaffold slides preparation. Fluorine-doped tin oxide (FTO) coated glass slides were laser etched to segregate anodal and cathodal sections of the cell. The slides were then cleaned thoroughly, first by hand and then in an ultrasonic bath—three cycles of 15 min in soap, Hellmanex 1% and deionised water. The dried substrates were then treated under argon plasma for 10 min. Next, the slides were spin coated with a 13.3% solution of Titanium disopopoxide bis(acetylacetonate) in ethanol (5000 rpm, 30 sec) and annealed on a hot plate (30 min, 450° C.). After cooling down, the substrates were immersed in a water based TiCl₄ solution (1.6 ml TiCl₄ 150 ml TDW) and placed in an oven at 70° C. for 30 min. Immediately after, the slides were dried and annealed at 450° C. for 30 min. Subsequent to cooling to room temperature, TiO₂ paste was screen printed using a 120 mesh polymer screen and sintered at 500° C. for 30 min on a hot plate. Later on, the aforementioned TiCl₄ treatment was repeated and was followed by the screen printing of ZrO₂ paste using a 120 mesh polymer screen which was then sintered (500° C., 30 min). The ITO paste was finally screen printed using a 45 mesh polymer screen and put in an oven at 600° C. for 90 min. To prepare Carbon based substrates, all fabrication steps were conducted in the same manner as for ITO cells, but instead of the ITO paste, a Carbon paste was printed and sintered at 500° C. for 30 min.

Perovskite solution preparation and FA_{0.85}MA_{0.15}PbI₃ two-step deposition. The mpITO scaffolds were inserted into an inert atmosphere glove box and heated on a hot plate (200° C., 30 min). Later, PbI₂ solution (2M, 0.5 ml) in a 85:15 DMF:DMSO mixture was prepared. 2 μl of the solution were cast onto the mpITO substrate's active area, and annealed on a 100° C. for 30 min. The substrates were then immersed in a 0.06 M solution of FAI:MAI at a ratio of 85:15 in isopropyl alcohol for 20 min, and then dipped in clean isopropyl alcohol for 5 sec. Subsequently, the cells were annealed on a hot plate (70° C.) for 30 min to finalize the preparation process.

Cell cleaning and restoration. The perovskite crystals embedded in the substrate were dissolved and washed away by dripping DMF on the cell (5 ml). The cleaned cells were then heated to 500° C. for 30 minutes. The subsequent deposition process was carried out following the same procedure, as described above.

SEM, FIB and EDS. To obtain a high quality cross section of the cell for scanning electron microscope (SEM) imagery and energy dispersive x-ray spectroscopy (EDS) analysis, a sample was placed inside a FEr” Helios NanoLab 460F1 and excavated using a focused Gallium ion beam (FIB) to expose the layered structure. The layered stack was imaged and measured, and a slab was retrieved and placed on a separate holder to enable a 90° EDS line scan. The EDS scan was conducted using electron beam energies between 5 kV and 30 kV in order to recognize the desired elements.

Absorbance and Transmittance. The absorbance measurements of substrates and cells were conducted using a VARIAN cary 5000 UV-VIS-NIR spectrophotometer equipped with a VARIAN DRA 2500 Diffuse Reflectance Accessory (integrating sphere). Transmittance measurements were carried out with a JASCO V670 spectrophotometer.

Work function. To determine the work function (WF) of a porous ITO film, a SKP5050-SPS040 model Kelvin Probe system was used. The contact potential difference (CPD) between the sample and the vibrating tip was measured with the sample inside a Faraday cage under ambient air environment. Before the measurement, the sample and tip were allowed to stabilise for about 30 min. The final WF value of the sample was calculated according to WFₛₐₘₚₗₑ=WFₜᵢₚ CPDₛₐₘₚₗₑ with the WF function of the tip was obtained using a gold coated calibration stage.

Hall Effect and conductivity. Hall Effect measurements and sheet resistivity calculations were conducted using a model 4804 AC/DC Hall Effect Measurement System, manufactured by Lake Shore Cryotronics.

PV characterization. Current-voltage curves and standard photovoltaic properties were obtained using a Newport solar simulator system consisting of an Oriel I-V test station using an Oriel So13A simulator. The solar simulator is class AAA for spectral performance, uniformity of irradiance, and temporal stability. It is equipped with a 450 W xenon lamp. The output power is adjusted to match AM1.5 global sunlight (100 mW/cm²). The spectral match classifications are IEC60904-9 2007, JIC C 8912, and ASTM E927-05. A silicon reference cell was used to calibrate the solar simulator equipped with an IR-cutoff filter (KG-3, Schott) in order to reduce the mismatch between the simulated light and AM 1.5 (in the region of 350-800 nm) to less than 2% with measurements verified at PV calibration laboratory (New Port, USA). J-V curves were obtained by applying a varying external bias on the cell and measuring the generated photocurrent with a Keithley model 2400 digital source meter. For standard measurements a forward voltage scan was conducted from 1 V to −0.1 V with voltage step and dwell times of 10 mV and 40 ms respectively. For hysteresis measurements a reverse voltage scan was conducted from −0.1 V to 1 V. Photovoltaic performance was measured using an opaque mask with an aperture area of 0.085 cm² (measured using an optical caliper). Cells were measured at least 24 hours after fabrication, and J-V curves were measured repeatedly until stabilization of the maximum power point.

External quantum efficiency (EQE) measurements were obtained using a custom made (by PV Measurements) IPCE device containing a Tungsten lamp for bias and a xenon lamp with a monochromator for wavelength scan. Measurements were conducted under no bias light or external voltage, in AC mode, using a light chopper set at 30 Hz. A standard silicon photodiode was used to calibrate the device.

CE and IMVS. Charge extraction (CE) and intensity-modulated photo-voltage spectroscopy (IMVS) were measured using Autolab Potentiostat-Galvenostat (PGSTAT) with a FRA32M LED driver equipped with a cool white light source. A Nova 2.1 software program was used to collect and analyze the obtained data. The CE measurement parameters used were as follows—discharge time of 2 seconds, illumination time of 5 seconds, delay times measured were 1, 1.2, 1.5, 1.9, 2.3, 2.9, 3.6, 4.4, 5.5, 6.8, 8.5, 10.5, 13, 16.1 and 20 seconds. The IMVS measurements were conducted by illuminating the sample at different light intensities, varying from 0.1 to 0.7 sun, with a sinusoidal wave modulation, with frequencies ranging from 1 Hz to 50 kHz. Lifetimes were calculated using the formula: τ=1/(2π-frequency at minimum of semicircle).

The structure and properties of ITO PSCs

An all-NP scaffold for perovskite solar cells was intriguing to research because of the immense interface and the nano-structured perovskite network that may crystalize in its cavities. In the search for a material suitable as a cathodic top contact for all-NP mesoporous perovskite solar cells, we were looking for properties of conductivity, stability and transparency. ITO is a conductive, rigid and transparent metal oxide used for versatile photoelectronic applications. Therefore, it was expected to render some of these qualities to a mesoporous thin film of sintered ITO nanocrystals. To be implemented in the cell structure, commercially available 50 nm ITO nano-powder was processed into a smooth textured paste suitable for screen-printing. A procedure reported initially for titanium dioxide paste was modified and utilized to prepare the ITO paste. The printed paste yielded mesoporous ITO films with thickness on the micrometer scale. Sintering temperatures of 600° C. allowed maximal conductivity of the film without compromising the other components of the cell. Hall Effect measurement of such a film, on a glass substrate, revealed sheet resistivity of 180.5 Ω/sq and carrier concentration of 8.7·10¹⁹ cm⁻³. The relatively high sheet resistivity, which is up to two orders of magnitude larger than a typical compact ITO thin film, is most likely a consequence of low crystallinity at the sintering sites and high defect concentration. The large surface area of the porous ITO is expected to suffer more defects than a planar film, thereby lowering the carrier concentration and increasing resistivity. On the other hand, the porous TO provides a huge increase in the surface area which is beneficial for the operation of the device.

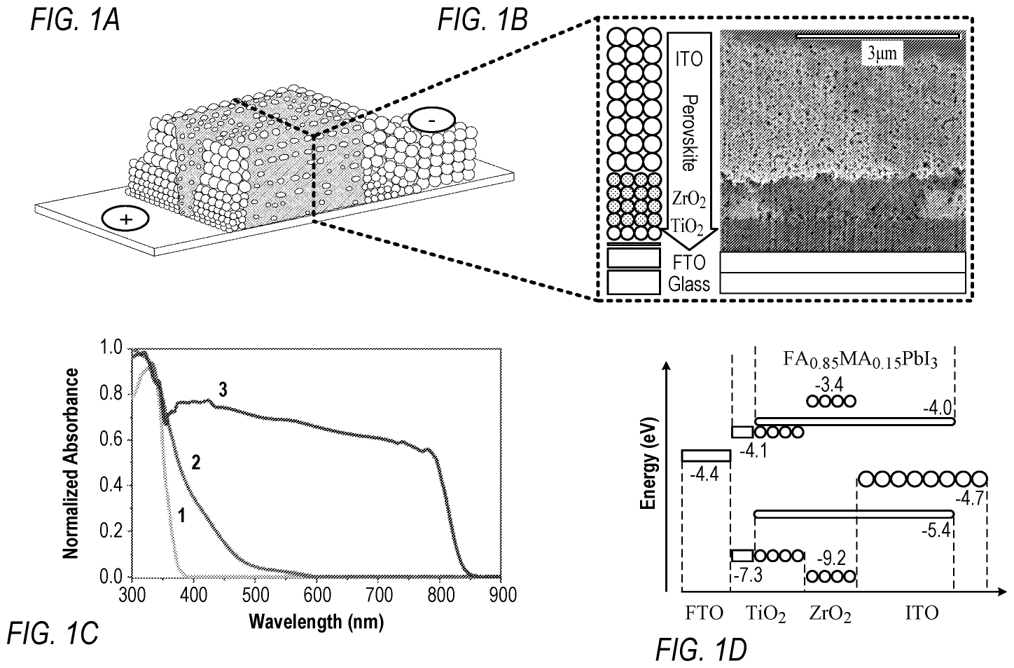

The entire solar cell is fabricated using scalable printing techniques and its basic structure is illustrated in FIG. 1A. The foundation of the cell, on top of which all functional layers are deposited, is a conductive fluorine doped tin oxide (FTO) coated glass which serves as the photo-anode of the cell. Originating as an ETL in the field of dye-sensitized solar cells, TiO₂ was found to be efficient for PSC technologies as well. Following the application of a compact TiO₂, a mesoporous film was screen-printed on the substrate, using a 20 nm diameter NP paste. An insulating mpZrO₂ was then printed on top of the mpTiO₂ using a 30 nm diameter NP paste. Thereafter, printing of ITO on top of the mpZrO₂ marks the final step in the construction of the scaffold and the penultimate process in the fabrication of a functional cell. In the concluding procedure, a perovskite precursor solution was allowed to seep through all three layers, and crystalize between the NPs of the scaffold. Under irradiation a closed circuit cell can now generate photocurrents and convert light to electrical energy.

A scanning electron microscopy (SEM) image of a typical cell cross section (FIG. 1B), cut using a focused ion beam (FIB), depicts the ordered three-layered structure on top of the FTO coated glass. As can be observed, the mpTiO₂ and mpZrO₂ layers are both ca. 1 μm thick and the mpITO layer is ca. 3.5 μm. Absorbance measurements, shown in FIG. 1C, reflect the steps in the cell construction. The absorbance curve of the complete FTO/mpTiO₂/mpZrO₂/mpITO scaffold extends slightly further into the visible range compared to the same configuration without mpITO (FIG. 1C curves 1-2), indicating the scaffold's semitransparency. The absorbance of a completed cell with deposited FA_{0.85}MA_{0.15}PbI₃, which will later be used for the PV characterization, spans across the visible range (FIG. 1C curve 3). While being irradiated, the scaffold allows most incident light to go through and be absorbed in the perovskite network. The energy level alignment of the materials in this structure, is presented in FIG. 1D. This alignment, together with the electron transport qualities of the TiO₂, dictate an inhomogeneous average diffusion of free charge carriers. Exited electrons are efficiently and preferentially collected by the ETL, while the holes are readily collected at the massive perovskite—ITO interface. In addition, the suitably situated energy levels of the components enable the efficient extraction of the absorbed photon energy and generate high measured photocurrents.

The concluding step of the cell synthesis is the perovskite deposition onto the scaffold. Since the sintered mpITO cathode permits lateral conductivity, the evaporation of an extra metal contact is unnecessary. This renders the cells fully printable and easy to prepare. The cell architecture permits the use of various solvents as well as a plethora of perovskite compositions. The utilization of perovskites containing various iodide to bromide ratios demonstrates the possibilities offered by the semitransparent scaffold. We have chosen to demonstrate the performance of mesoporous ITO based PSCs (ITO-PSCs) using a mixed cation perovskite composition of formamidinium and methylammonium lead iodide. This composition maximized our results after the optimization process of the deposition procedure. Besides the optimal crystallization conditions usually pursued in the synthesis of common PSCs, further criteria are essential for ITO-PSCs. The ample percolation of the perovskite solution through the nanometric cavities between the NPs of all layers is imperative. Additionally, to diminish the formation of empty voids in the network, following the crystallization of the perovskite and the evaporation of solvents, high concentration precursor solutions are preferred.

Optimal conditions for the FA_{0.85}MA_{0.15}PbI₃ perovskite were found to involve a two-step deposition method using high concentration of hot precursor solution. The two-step deposition method begins, with the administration of a metal halide solution on top of the substrate. A concentrated hot solution (2M, 70° C.) of PbI₂ in 85:15 ratio of DMF:DMSO was casted onto the mpITO layer in a nitrogen filled glove box. By annealing the substrates at 100° C. for 30 min, a PbI₂ DMSO complex is formed. In the second step of the deposition process the cells were reacted with a solution of FAI:MAI (85:15) in isopropyl alcohol (IPA). Finally, annealing on a 100° C. hot plate for 30 min resulted in a black uniform perovskite surface. A top view SEM image displays a pin hole free surface. In order to further characterize the composition and structure of the cell, and to assess the extent of the perovskite infiltration within it, an energy dispersive X-ray spectroscopy (EDS) analysis was performed on a cross-section of the cell. A focused ion beam (FIB) was used to excavate a cut through a completed cell, revealing its layered structure. The cross-section was scanned and its elemental composition was analyzed and expressed as counts per second of the element specific emission lines.

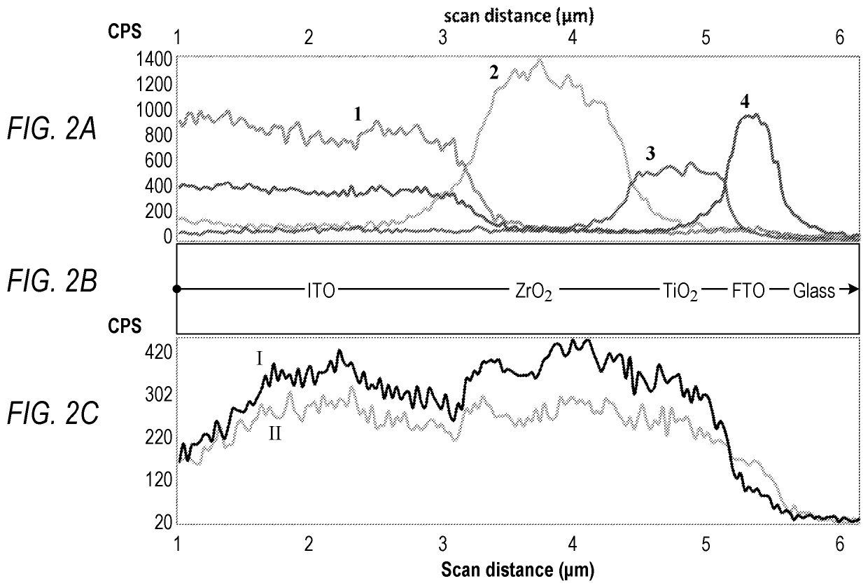

FIG. 2A depicts the distribution of the main scaffold elements as a function of the sample depth. According to the EDS analysis, indium (curve 1) and tin (curve 4) atoms dominate the first 3 μm of the scan line. Deeper into the sample, signals of zirconium (curve 2), titanium (curve 3) and tin atoms appear as three separate well defined bands. This elemental mapping matches the FTO/mpTiO₂/mpZrO₂/mpITO structure and is in spatial agreement with the concomitant SEM image of the measurement area (FIG. 2B). The boundaries between the different layers in this image are evident. In the same measurement the distribution of the heavier perovskite elements is determined and is presented in a separate image for clarity (FIG. 2C). Detection of iodine and lead (curve I-II) is important to identify the degree of percolation of the FA_{0.85}MA_{0.15}PbI₃ perovskite inside the mesoporous scaffold. Moreover, in this porous solar cell architecture the perovskite does not form a separate layer and is therefore virtually undetectable using SEM imagery, giving this method particular importance in the characterization of the imbedded perovskite network.

Photovoltaic performance of ITO PSCs

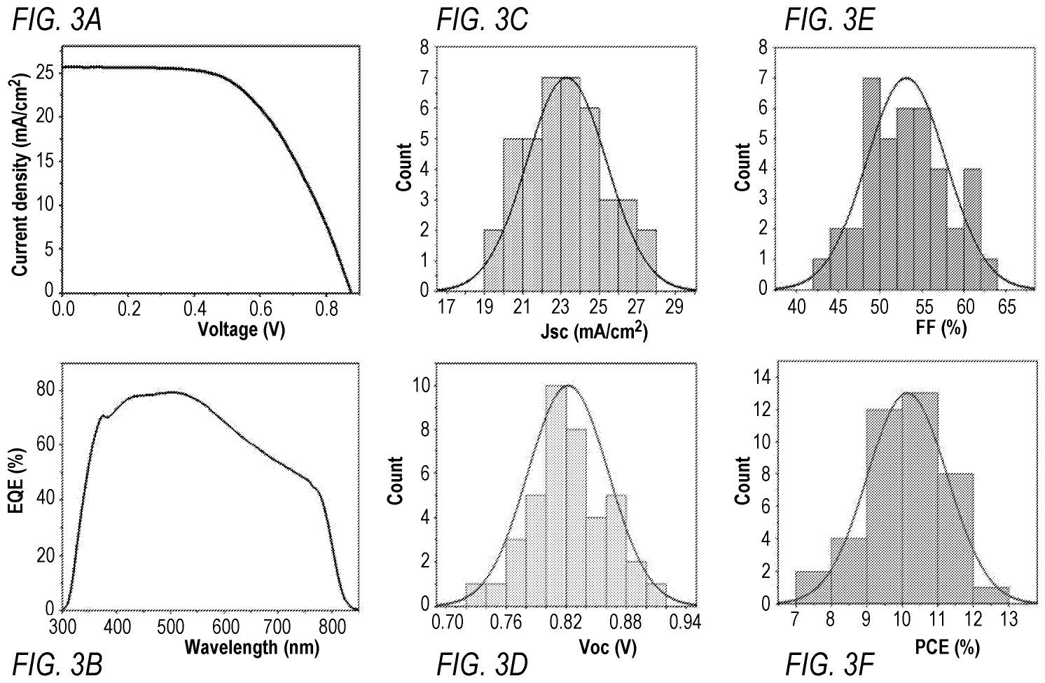

A series of forty ITO-PSCs were manufactured for the analysis of photovoltaic properties. These cells were deposited with FA_{0.85}MA_{0.15}PbI₃ perovskite by a two-step deposition method. Current density to voltage plot of the best performing cell is presented in FIG. 3a. This cell reached a PCE of 12.7% with open circuit voltage (V_{oc}) of 0.88 V and Current density (J_{sc} of 25.66 mA/cm. An external quantum efficiency (EQE) measurement for a typical cell is presented in FIG. 3B. A J_{sc} histogramme for the measured group of cells is presented in FIG. 3C. An average current density of 23.3 mA/cm² with standard deviation of 2.1 mA/cm² was received. These photocurrents exhibit the ability of the ITO-PSCs to successfully convert light energy into free charges and deliver them up to the contacts. These facts may be attributed to the enormous interface of both mpTiO₂ and mpITO with the perovskite network. Since ZrO₂ is an insulator, for every exciton formed, the electron and hole must have crossed accumulatively the whole mpZrO₂ layer. Hence it is striking that the charges went through over 1 μm of thickness inside the labyrinth of perovskite network between the ZrO₂ NPs with such efficiency. The V_{oc} histogramme presented in FIG. 3D shows an average of 0.82 V and maximal values of 0.9 V. Although these voltages are not comparable to state-of-the-art HTM-containing devices using a similar perovskite composition, they constitute reasonable values for HTM-free cells. These type of cells possess structurally intrinsic lower V_{oc} capabilities due to the extra over-potential necessary between the cathode and the perovskite. The fill factor (FF) is an important indicator of the cell's capability to produce photocurrents despite an opposing, externally induced, voltage during the J-V measurements. The FF histogramme in FIG. 3E shows the majority of the cells ranging between values of 48% and 58%. These values limit the achievable cell PCEs. A further improvement of the FF can be achieved by a better mpITO film. Finally, the PCE histogramme in FIG. 3F presents a rather narrow distribution of values, averaged at 10.1%, with over half of the cells exceeding 10% efficiency. The cells exhibit good reproducibility and a relatively low degree of hysteresis.

Stability and Renewability of ITO-PSCs

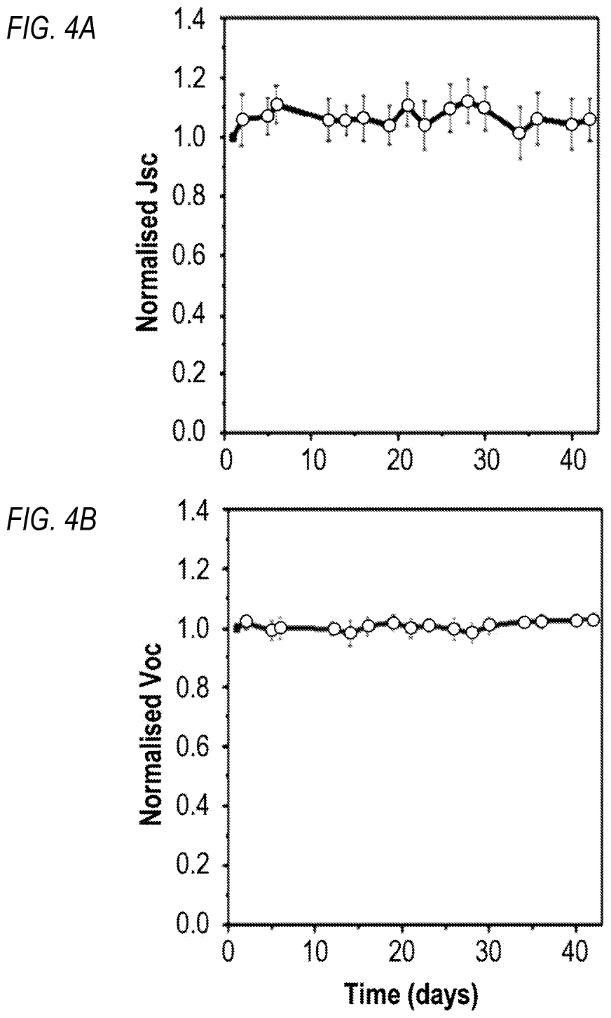

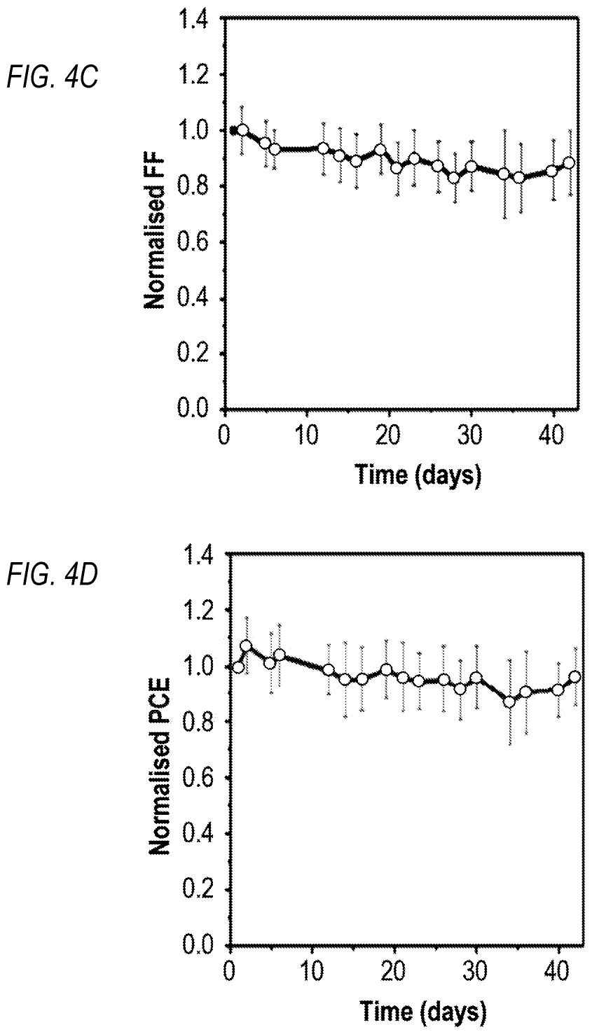

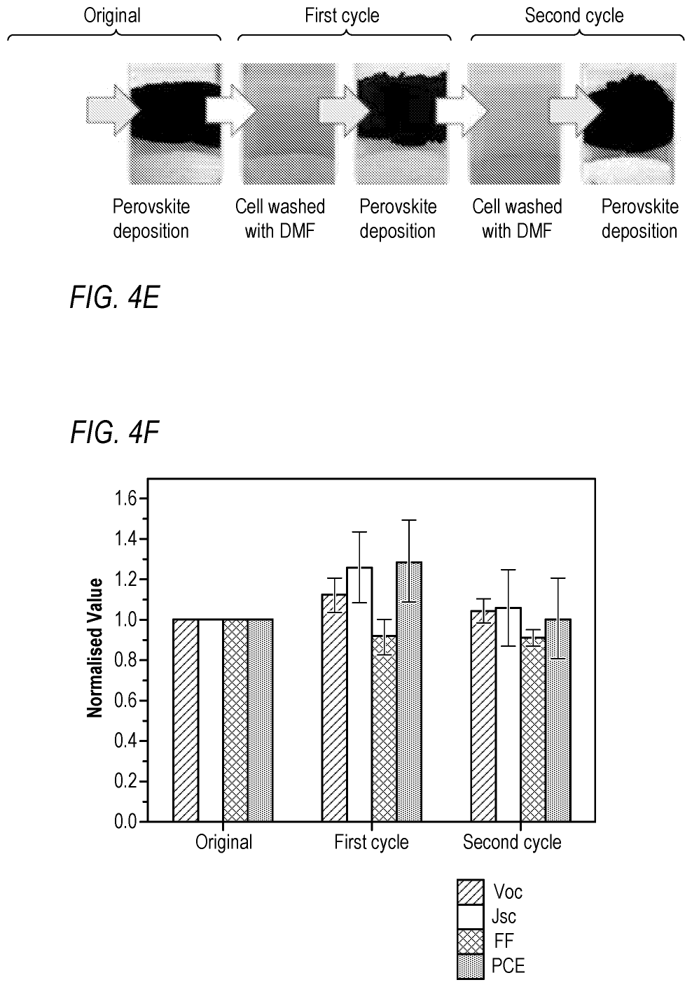

Stability measurements were carried out for a group of unencapsulated cells. These FA_{0.85}MA_{0.15}PbI₃ perovskite cells were kept under ambient atmosphere conditions and repeatedly measured for a period of over forty days. The development of photovoltaic parameters over that time period is presented in FIG. 4A-D. It is noticeable that the average J_{sc} and V_{oc} values remain stable. As a result, the average PCE of the cells retains 96% of the cells initial efficiencies. Other types of PSC configurations with similar perovskite compositions do not typically preserve their photovoltaic parameters as well when unencapsulated. The decline in performance is usually attributed to moisture and oxygen related perovskite degradation. It is therefore conceivable to assume that the stability of the ITO-PSCs stems from the perovskite's protected environment within the nanometric pores of the rigid scaffold.

The renewability of ITO-PSCs originates from a number of structural qualities rooted in their unique design. Specifically the chemical and thermal stabilities of the scaffold enable the complete removal of an existing degraded perovskite network and the restoration of the scaffold's bare surface. While the material recycling of old PSCs has been demonstrated in the past, it is notable that the major part of the cost of PSCs is related to the manufacturing of the anode, HTM, and the back contact. This fact, together with the unresolved issue of perovskite degradation on the years scale, induces a benefit in the ability to remove and replace solely the perovskite in a cell, without compromising or removing other components.

It was found that ITO-PSCs may be rinsed thoroughly with dimethylformamide for the removal of the perovskite from the scaffold. However, the ensuing application of new perovskite did not bring about a good restoration of the cell. It was only once an additional annealing of the rinsed scaffold (at 500° C. for 30 min) was performed, that the cells could be restored and reach their initial photovoltaic performances. Pictures of a device which was repeatedly rinsed and renewed using this procedure are exhibited in FIG. 4E. The photovoltaic parameters of 8 cells were monitored throughout repeated restoration cycles, and are summarized in FIG. 4F. Both restoration cycles yielded a slightly higher average J_{sc} and V_{oc}, relative to the initial deposition, while the FF decreased by a few percent. Despite these changes, most likely caused by minor operator inconsistency during redeposition, the retention of the photovoltaic parameters is evident. The average PCE of the ITO-PSCs fully restored after each cycle.

Charge Extraction and Intensity Modulated Photovoltage Spectroscopy

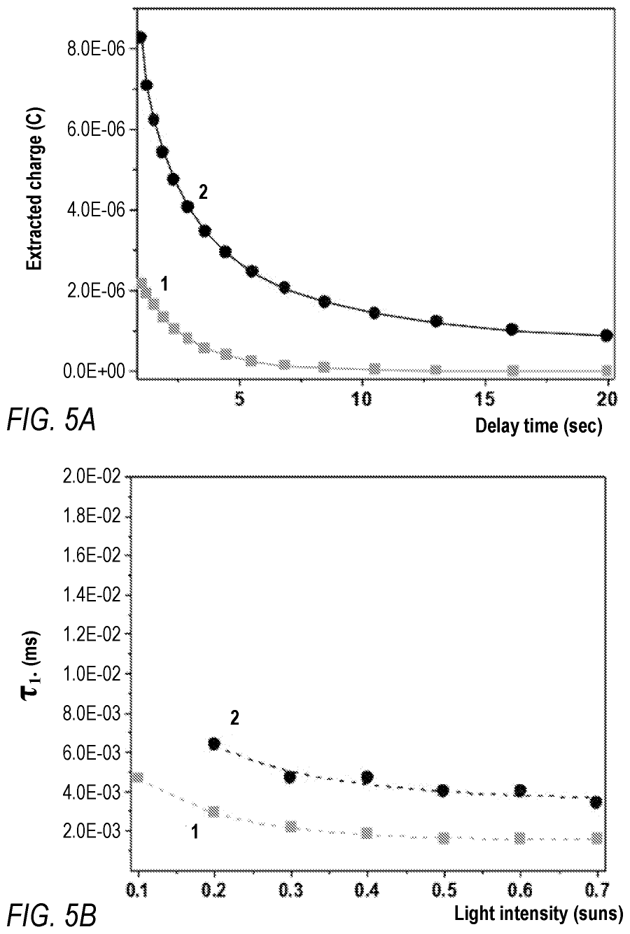

To further investigate the physical properties of this new solar cell type, charge extraction (CE) and Intensity modulated photovoltage spectroscopy (IMVS) measurements were carried out. The CE measurement is conducted by illuminating the cell for 5 seconds under open circuit conditions then switching off the light and allowing the internal charges to decay for a varying period of time (delay time). Subsequently, the cell is short circuited and the remaining charge is extracted and quantified. FIG. 5A plots the extracted charge as a function of the delay time before a short circuit was induced, for both an ITO-PSC (curve 1) and a carbon cathode PSC (curve 2) which bares resemblance in structure and was prepared using the same perovskite composition. The measurements show a faster decay of charges in the ITO cell compared with the carbon cell. The decay of charges in the cell reflects the recombination of free charge carriers generated by the initial illumination. Since the recombination lifetime within the perovskite is on the order of nanoseconds, it is widely thought that the observed retention of charges over several seconds represents the existence of trap states on the perovskite—scaffold interface. These states enable prolonged segregation of the charge carriers. The amount of charge extracted in the CE measurements is therefore assumed to be indicative of the presence of traps at the cell's interfaces. Though traps are usually regarded as disruptive in semiconductor devices, their ability to delay recombination may increase the probability of charges reaching the contacts, thereby improving cell performance. Our measurements showed that charges are retained longer in the carbon cell compared to the ITO cell. This result may correspond to the higher photovoltaic performances of the carbon PSCs, with state-of-the-art devices achieving up to 15.7% PCE.

IMVS was used to study the recombination behavior in the ITO-PSCs. For comparison, carbon cathode PSCs, prepared similarly and containing the same perovskite composition, were measured with IMVS as well. In this technique the cell was illuminated by white light with modulated pulse frequencies ranging between 1 and 10⁵ Hz. When measuring the transfer function, the impedance of the cell can be assessed and an equivalent circuit can be assigned to it. This basic IMVS measurement was repeated at different light intensities ranging from 0.1 to 0.7 Sun. When plotting the impedance in the complex plane, two semicircles were observed for each light intensity. One semicircle appears at high frequencies of 10⁴-10⁵ Hz and the other at lower frequencies of around 10² Hz. By identifying the frequency at the minimum of each semicircle, one can extract the characteristic lifetime it represents. The first set of semicircles, found at high frequencies (10⁴-10⁵ Hz), corresponds to lifetimes on the order of 10⁻³-10⁻² ms, whereas the second set, observed at lower frequencies (10² Hz), corresponds to lifetimes on the order of 0.1-1 ms. Both lifetimes show a negative exponential dependence on the light intensity. It is generally believed that this type of dependency originates from the direct influence of light intensity on the charge carrier density in the perovskite. The higher the carrier density, the higher the probability of oppositely charged carriers encountering each other and recombining, thereby decreasing their average lifetime. The longer of the two observed lifetimes is commonly assigned to the behavior of charges in the TiO₂ which possesses intrinsically slower recombination rates. The shorter lifetime, on the other hand, is usually attributed to charge recombination in the perovskite itself. In FIG. 5B, a comparison of the ITO-PSCs (curve 1) and the carbon PSCs (curve 2) reveals that though the ITO-PSCs possess slightly shorter lifetimes, they are well within the same regime as the carbon cells. This finding suggests that the structural differences between these two cell types has no significant effect on recombination lifetimes in the perovskite, as is expected considering the use of the same perovskite composition.

In conclusion, a new configuration for perovskite solar cells is presented. These mesoporous Indium Tin Oxide perovskite solar cells revealed high photocurrents and extremely high stability for unencapsulated cells. These properties are derived from the unique all-NP scaffold and the interlaced perovskite network which is crystalized within its cavities. Other than being fully printable, the cells were proven to be entirely renewable. Removing the perovskite allowed the application of a new one, and the retrieval of the initial photovoltaic performances. Since these cells permit direct solution perovskite deposition as a final step, we consider this architecture to be a general platform for the fabrication of solar cells and various optoelectronic devices.

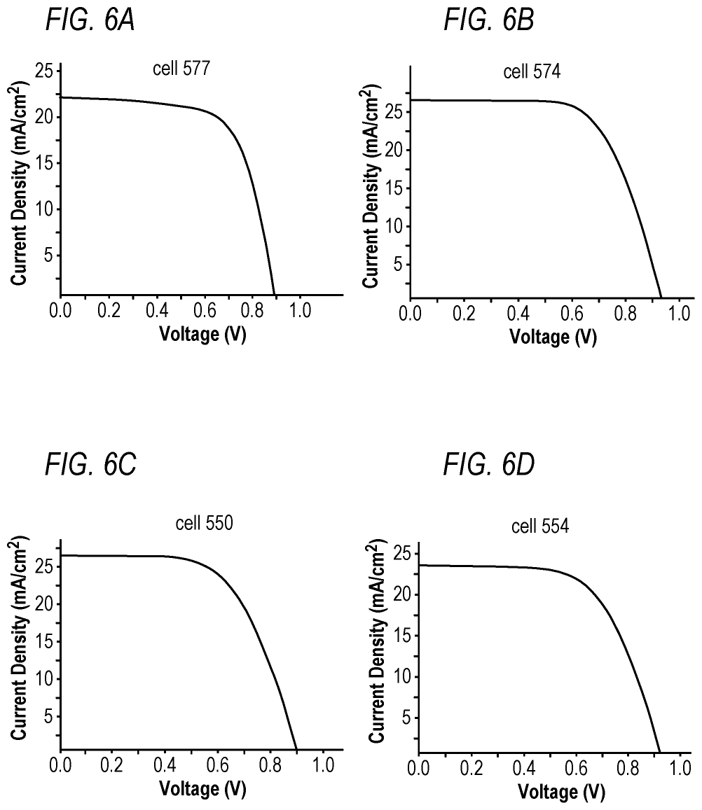

Further optimization of the ITO perovskite-based cells show higher photovoltaic performance then before and more consistent results as can be observed in Table 1. The corresponding current voltage curves are observed in FIG. 6. The main improvement of the cells is mainly due to the development of the ITO paste which is based on NPs as described in details herein

TABLE 1
Photovoltaic parameters of representative
ITO solar cells.

| | Voc | Jsc | | |
|---|---|---|---|---|
| Cell | (V) | (mA/cm2) | FF % | Eff % |
| 550 | 0.903 | 26.36 | 61.05 | 14.54 |
| 554 | 0.926 | 23.472 | 62.36 | 13.55 |
| 567 | 0.891 | 24.417 | 62.55 | 13.61 |
| 574 | 0.934 | 26.59 | 65.1 | 16.17 |
| 577 | 0.894 | 21.909 | 67.21 | 13.16 |

1.-39. (canceled)

40. A perovskite-based photovoltaic device comprising a layered inorganic scaffold structure and a layer of at least one perovskite material interpenetrating said layered scaffold structure, wherein the layered scaffold structure comprises a transparent layer of a conductive metal oxide material, a mesoporous layer of an insulating metal oxide material and a layer of a mesoporous conductive indium tin oxide.

41. The device according to claim 40, wherein the layered scaffold structure is an all-particle inorganic structure.

42. The device according to claim 40, wherein the layered scaffold structure comprises a conductive metal oxide layer comprising or consisting at least one mesoporous conductive metal oxide selected from TiO₂ and ZnO; an insulating metal oxide layer comprising or consisting at least one mesoporous insulating metal oxide selected from ZrO₂ and Al₂O₃ and a layer comprising or consisting at least one mesoporous ITO or FTO nanoparticles.

43. The device according to claim 42, wherein the layer comprising or consisting ITO or FTO nanoparticles is overlaid with a layer of at least one perovskite material.

44. The device according to claim 43, comprising a layer of a conductive metal oxide provided as a mesoporous layer, as an amorphous mesoporous form, in a crystalline mesoporous form or in a compact form; a layer of a mesoporous insulating metal oxide; a layer of a mesoporous ITO or FTO NPs; and a layer of at least one perovskite material.

45. The device according to claim 40, wherein the layered scaffold structure is formed on a substrate material, wherein the substrate is optionally a photoanode.

46. The device according to claim 40, wherein the layered scaffold structure is [a conductive metal oxide layer]/[an insulating metal oxide layer]/[an ITO or FTO NPs layer].

47. The device according to claim 40, wherein the layered scaffold structure is formed on a photoanode and is of the structure is [photoanode]/[a conductive metal oxide layer]/[an insulating metal oxide layer]/[an ITO or FTO NPs layer].

48. The device according to claim 40, having the structure [a conductive metal oxide layer]/[an insulating metal oxide layer]/[an ITO or FTO NPs layer]/[perovskite layer].

49. The device according to claim 40, having the structure [photoanode]/[a conductive metal oxide layer]/[an insulating metal oxide layer]/[an ITO or FTO NPs layer]/[perovskite layer].

50. The device according to claim 40, being selected from
(1) FTO/mpTiO₂/mpZrO₂/mpITO/Perovskite;
(2) FTO/compact TiO₂/m pZrO₂/m pITO/Perovskite;
(3) FTO/crystalline mpTiO₂/mpZrO₂/mpITO/Perovskite;
(4) FTO/amorphous mpTiO₂/m pZrO₂/mpITO/Perovskite;
(5) FTO/compact TiO₂/m pZrO₂/FTO np/Perovskite;
(6) FTO/crystalline mpTiO₂/mpZrO₂/FTO np/Perovskite; and
(7) FTO/amorphous mpTiO₂/mpZrO₂/FTO np/Perovskite.

51. The device according to claim 40, formed by 3D printing, inkjet printing, screen printing or silk printing.

52. A process for manufacturing a perovskite-based device comprising a layered scaffold structure and at least one perovskite material interpenetrating said layered scaffold structure, the process comprising forming on a layered scaffold structure being free of organic materials, a layer of at least one perovskite material under conditions permitting interpenetration of the at least one perovskite material through the scaffold structure.

53. The process according to claim 52, the process comprising forming the layered scaffold structure by stacking alternate layers of insulating and conducting particulate materials, said layered scaffold structure being free of organic materials, and overlaying said layered scaffold structure with a layer of at least one perovskite material under conditions permitting interpenetration of the at least one perovskite material through the scaffold material.

54. The process according to claim 52, wherein the layered scaffold structure is on a surface region of a substrate.

55. The process according to claim 53, wherein the layered scaffold structure is formed on a surface region of a substrate.

56. The process according to claim 52, wherein the substrate is a photoanode.

57. The process according to claim 52, the process comprising:
forming a layer of at least one conductive metal oxide material on a substrate, the at least one conductive metal oxide being in a form selected to provide a mesoporous layer, an amorphous mesoporous layer or a crystalline mesoporous layer or a compact layer; or forming the layer under conditions selected to provide a mesoporous layer, an amorphous mesoporous layer or a crystalline mesoporous layer or a compact layer;
forming a mesoporous layer of at least one insulating metal oxide material on said layer of the at least one conductive metal oxide material;
forming a mesoporous layer of ITO on said mesoporous layer of at least one insulating metal oxide material; and
forming a perovskite layer on said ITO layer under conditions permitting penetration of said perovskite material through all mesoporous layers.

58. The process according to claim 57, wherein each of the process steps is carried out by printing.

59. A device according to claim 40, when implemented in a photovoltaic cell, a light emitting diode (LED) or a lasing system.
